(19) United States
(12) Patent Application Publication
(10) Pub. No.: US 2007/0170995 A1
(43) Pub. Date: Jul. 26, 2007

(54) Plasma generating devices and methods for using the same

(76) Inventors: David T. Dutton, San Jose, CA (US); Arthur Schleifer, Portola Valley, CA (US); Robert Taber, Palo Alto, CA (US); Karen L. Seward, Portola Valley, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/485,222

(22) Filed: Jul. 11, 2006

Related U.S. Application Data
(60) Provisional application No. 60/760,872, filed on Jan. 20, 2006.

(51) Int. Cl. H03B 7/14

(52) U.S. Cl. 331/107 R

(57) ABSTRACT

Aspects of the invention include plasma generating devices and systems thereof, as well as methods of using the same in plasma generation. Embodiments of the plasma generating devices include a resonator having a discharge gap and a ground plane disposed on opposing sides of a substrate; and a gas flow element configured to flow gas through the discharge gap. In using the plasma generating devices, a gas is flowed through the discharge gap and sufficient power is applied to the resonator to produce a plasma, e.g., in the form of a plasma jet, at the discharge gap. The subject devices and methods find use in a variety of different applications.

### CROSS REFERENCE To RELATED APPLICATIONS

Applicant claims the benefit under 35 U.S.C. § 119(e) of prior U.S. provisional application Ser. No. 60/760,872 filed Jan. 20, 2006, the disclosure of which is incorporated herein by reference.

### BACKGROUND

A plasma is an ionized gas, and is usually considered to be a distinct phase of matter. “Ionized” in this case means that at least one electron has been dissociated from a proportion of the atoms or molecules. The free electric charges make the plasma electrically conductive so that it couples strongly to electromagnetic fields. The term plasma is generally reserved for a system of charged particles large enough to behave as one. Even a partially ionized gas in which as little as 1% of the particles are ionized can have the characteristics of a plasma (i.e., respond to magnetic fields and be highly electrically conductive).

Microwave plasma sources recently have been described [A. M. Bilgic et al., (2000), “A New Low-Power Microwave Plasma Source Using Microstrip Technology For Atomic Emission Spectrometry” Plasma Sources Sci. Technol 9:1-4; A. M. Bilgic et al., (2000) “A Low-Power 2.45 GHz Microwave Induced Helium Plasma Source At Atmospheric Pressure Based On Microstrip Technology”, J. Anal. At. Spectrom., 15:579-580]. The plasma sources described in these articles produce an electric field across a gap between a microstrip line present on one side of a dielectric and a ground plane on the opposite side of the dielectric. In these devices, the gap is defined by the dielectric thickness of the device, which typically is in the range of 0.5-1 mm. The structure is not resonant and produces relatively low voltages across the gap (approx 30V) for relatively large power inputs (15-20 W), which is sufficient voltage to sustain a plasma, but not enough voltage to strike a plasma and hence an external piezoelectric device has been used to initiate the plasma in these references.

Hopwood et al., (U.S. Pat. No. 6,917,165; herein incorporated by reference for its description of microwave frequency plasma generating devices) describes the use of a microstrip resonator at microwave frequencies for producing “non-thermal” plasmas at a gap in the same plane as the resonator. The circumference of the ring is a ½ wavelength at the operating frequency, and the location of the gap relative to the incoming microwave feed is designed to optimize the resonator's input impedance and maximize return loss at resonance. Voltages at the resonator ends on either side of the gap are 180° out of phase. The electric field at the gap is further enhanced by √Q of the resonator, where Q is the quality factor of the resonator [Q=2π (energy stored/energy dissipated)], and the small gap dimension (in general less than 50 μm), such that high electric fields are available to discharge a gas across the gap.

There is continued interest in the development of new devices and systems that can be employed for producing plasmas.

### SUMMARY

Aspects of the invention include plasma generating devices and systems thereof, as well as methods of using the same in plasma generation. Embodiments of the plasma generating devices include a resonator having a discharge gap and a ground plane disposed on opposing sides of a substrate; and a gas flow element configured to flow gas through the discharge gap. In using the plasma generating devices, a gas is flowed through the discharge gap and sufficient power is applied to the resonator to produce a plasma, e.g., in the form of a plasma jet, at the discharge gap. The subject devices and methods find use in a variety of different applications.

### BRIEF DESCRIPTION OF THE FIGURES

FIGS. 1A and 1B provide two views of plasma generating device according to an embodiment of the invention.

FIG. 2A provides a schematic view of a device with a gas feed connector according to an embodiment of the invention, while FIG. 2B provides a photograph of a device with a gas feed connector as shown in FIG. 2A.

FIG. 3 provides a photograph of a plasma generating device according to an embodiment of the invention that is being employed to produce a plasma jet.

### DETAILED DESCRIPTION

Aspects of the invention include plasma generating devices and systems thereof, as well as methods of using the same in plasma generation. Embodiments of the plasma generating devices include a resonator having a discharge gap and a ground plane disposed on opposing sides of a substrate; and a gas flow element configured to flow gas through the discharge gap. In using the plasma generating devices, a gas is flowed through the discharge gap and sufficient power is applied to the resonator to produce a plasma, e.g., in the form of a plasma jet, at the discharge gap. The subject devices and methods find use in a variety of different applications.

Before the present invention is described in greater detail, it is to be understood that this invention is not limited to particular embodiments described, and as such may vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

Plasma Generating Device

As summarized above, the invention provides plasma generating devices. Embodiments of the invention are capable of producing plasmas under non-static atmospheric conditions. By non-static atmospheric conditions is meant that the plasma is produced in an environment in which gas, including air, is moving. Embodiments of the subject plasma generating devices exhibit a low plasma bias, such that they have a long life-time. By long life time is meant that the devices can be employed to continuously produce a plasma without substantial degradation of the device, e.g., as may be caused by ion bombardment at electrical contacts. In certain embodiments, the devices can be employed to generate a plasma without substantial degradation in function for a period of time up to 50 hours of continuous operation or longer, such as up to 100 hours or longer and including up to 1000 hours or longer. Degradation in function can be measured by any convenient method.

Embodiments of the subject plasma generating devices are capable of producing atmospheric plasma with lower power inputs than those inputs employed for devices that are configured to generate plasmas under static conditions. In certain embodiments, the devices of the invention can produce atmospheric plasmas using applied power ranging from about 0.1 W to about 50.0 W, such as from about 0.1 W to about 20 W and including from about 0.5 W to about 8 W.

Embodiments of the plasma generators of the invention include the following elements: a substrate having a first surface and a second surface; a resonator having a discharge gap disposed on said first surface of said substrate; a ground plane disposed on said second surface of said substrate; a connector coupled to said resonator for connecting a power source to said resonator; and a gas flow element configured to flow gas through said discharge gap. Aspects of these components are reviewed in greater detail below.

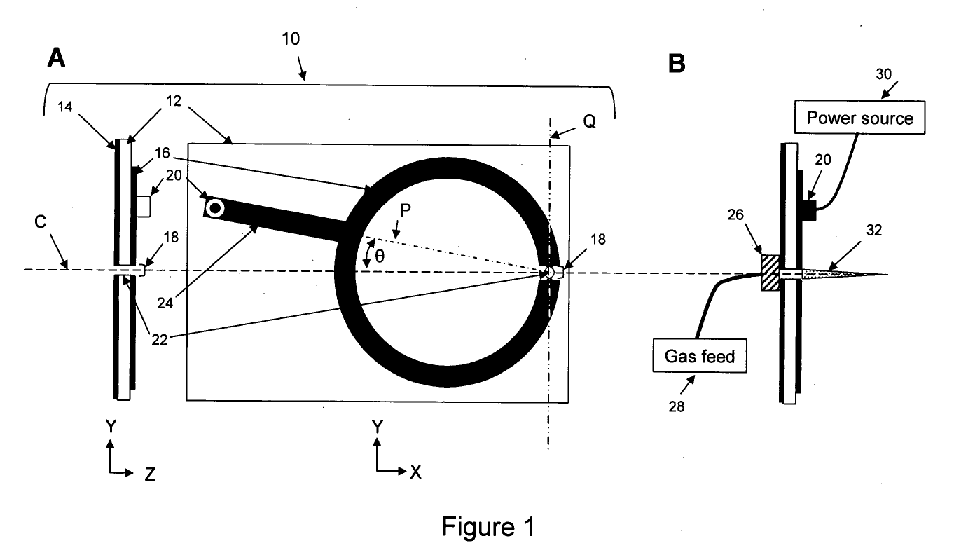

An embodiment of a plasma generating device of the invention is illustrated in FIG. 1A. Plasma generating device 10 contains a planar substrate 12 (planar in the X/Y plane) having a resonator in the form of a microstrip resonant ring 16 with a discharge gap 18 disposed on a first side of the planar substrate 12 and a ground plane 14 disposed on a second side of the substrate 12. The microstrip resonant ring is coupled to a connector 20 for connecting a power source that supplies power to the microstrip resonant ring resonator. The connector may be directly attached to the microstrip resonant ring (not shown) or coupled to the microstrip resonant ring via a transmission line 24. The plasma generating device contains a gas flow element 22 configured to flow a stream of gas through the discharge gap 18, e.g., during plasma generation. In the embodiment shown in FIG. 1, the gas flow element 22 is configured to flow gas substantially orthogonally to the X/Y plane (i.e., substantially in the Z direction). Gas flow and gas flow elements are described in greater detail below.

In certain embodiments of the plasma generating devices of the invention, the connector 20 (with or without transmission line 24) and the discharge gap are disposed in positions on the microstrip resonant ring to provide an impedance matched to that of a power source. By “matched” is meant that the impedance that is presented at the connector 20 is equivalent to the output impedance of the power source such that maximum power transfer can be obtained. Any difference in these two impedance can result in a reflected component of power at connector 20 back towards the power source. In certain embodiments, the circumference of the microstrip resonant ring is one-half wavelength (λ/2) at the operating frequency of the plasma generating device. The angle (θ) between the centerline of the microstrip resonant ring (dashed line C in FIG. 1A) and the line connecting the connector coupling and the discharge gap (dashed line P in FIG. 1B) is such that the impedance measured at the power input at connector 20 is matched to that of the power supply. When power is applied to the microstrip resonant ring, a maximum voltage difference occurs across the discharge gap 18. In certain embodiments, the magnitude of this maximum voltage difference ranges from about 50V to about 750V, such as from about 75V to about 600V and including from about 120V (0.5 W, 50 ohm, Q=110) to about 475V (8 W, 50 ohm Q=110). Thus, the electric field is concentrated in the discharge gap and, in certain embodiments, is at least double the magnitude of the electric field between the microstrip resonant ring and the ground plane. The microstrip dimensions and discharge gap length are determined in the design of specific embodiments to achieve the intended resonant frequency and performance characteristics of the device, e.g., as exemplified below.

The discharge gap of the resonator can have a variety of dimensions and configurations so long as it is configured to provide for striking of plasma under conditions of use. In certain embodiments, the discharge gap is over the surface of the substrate whereas in other embodiments, the discharge gap extends into or through the substrate. The discharge gap of the microstrip resonant ring can vary in size, where the dimensions of the gap are selected to provide for plasma striking of a gas flowing through the gap under intended parameters of use. In certain embodiments, the gap has a width (i.e., the distance between ends of the resonator) that ranges from about 20 μm to about 1 mm, such as from about 50 μm to about 500 μm and including from about 140 μm to about 200 μm.

In certain embodiments, the substrate 12 is a dielectric material that has a high dielectric constant. By high dielectric constant is meant a dielectric constant that is 2 or higher, such as 5 or higher, including 9.6 (e.g., ceramic) or higher. Dielectric materials that find use as substrates in the invention include, but are not limited to, ceramic compounds, Teflon, polymers, glass, quartz and combinations thereof. For embodiments that are operated in air, then hard dielectrics with no organic component are required, such as ceramic, glass and quartz. In certain embodiments the substrate is fabricated from a single material whereas in certain other embodiments the substrate contains more than one material, e.g., different layers of distinct materials. The dimensions of the substrate can vary widely depending on the intended use of the plasma generated by the plasma generating device and/or the nature of the dimensions of the microstrip resonant ring employed, which are a function of the substrate dielectric properties, the frequency of operation and the required characteristic impedance. In certain embodiments, the substrate is a planar substrate and has a length ranging from about 5 mm to about 100 mm, such as from about 10 mm to about 70 mm and including from about 20 mm (actual ceramic) to about 50 mm (actual RT/DUROID®); a width ranging from about 5 mm to about 100 mm, such as from about 10 mm to about 70 mm and including from about 12 mm (actual ceramic) to about 40 mm (actual RT/DUROID®) and a thickness ranging from about 100 μm to about 5 mm, such as from about 100 μm to about 2 mm and including from about 1 mm (actual ceramic) to about 2 mm.

As indicated above, in embodiments of the invention the ground plane 14 and the microstrip resonant ring 16 are disposed on opposing sides of substrate 12 and as such are not in physical contact with each other. The distance between the ground plane and the microstrip resonant ring may vary, where in certain embodiments the distance between these two components may range from about 100 μm to about 5 mm, such as from about 100 μm to about 2 mm and including from about 1 mm to about 2 mm. In certain embodiments, the ground plane and the microstrip resonant ring are made of the same material, while in certain other embodiments they are made of different materials. The ground plane and/or microstrip resonant ring can be fabricated from a variety of different materials including, but not limited to, Au, Cu, Ag and the like. The thickness of the microstrip resonant ring layer and the ground plane layer can vary. In certain embodiments, the ground plane has a thickness ranging from about 1 μm to 50 μm, including from about 1 μm to 25 μm, such as from about 2 μm to about 10 μm, and including from about 6 μm to about 6.5 μm. In certain embodiments, the microstrip resonant ring has a thickness ranging from about 1 μm to 50 μm, including from about 1 μm to 25 μm, such as from about 2 μm to about 10 μm, and including from about 6 μm to about 6.5 μm. In certain embodiments, the thickness of the ground plane and the microstrip layer is the same (or similar) whereas in other embodiments the thicknesses of these two components is different.

The resonators, e.g., microstrip resonant rings, and their respective discharge gaps of the invention can take a variety of shapes. Thus, the term “ring” is not to be limited to only a circular ring but is intended to refer to any circular or non-circular shaped structure, where structures of interest include, but are not limited to: circular, elliptical or oval and other non-circular rings, and rectangular or other multisided shapes. The microstrip resonant ring can be disposed on the substrate in a variety of ways. In certain embodiments, the substrate is coated with material for the microstrip layer (e.g., Au, Cu, etc.) and the microstrip resonator structure is formed by photo-lithographic and wet etching techniques which themselves are known in the art. Other processing techniques can be used to form the microstrip resonator structure.

As indicated above, the resonator is coupled to a connector 20 for connecting a power source that supplies power to the resonator during operation. The connector may be any of a variety of known connectors. In certain embodiments, the connector is a subminiature type A (SMA) coaxial connector attached at right angles to the microstrip resonant ring and used to couple power to the device (e.g., as described. U.S. Pat. No. 6,917,165, the disclosure of which is herein incorporated by reference). Edge mounting SMA connectors can also be used.

In certain embodiments, the connector is linked to the resonator by an additional transmission line 24. The design of the resonator geometry gives a primary impedance transformation, and no further transformation is required, hence the length of the additional transmission line does not effect the overall impedance of the device. However if the range of impedance transformation is not fully accommodated by the geometry of the resonator, then the transmission line 24 can be used as a further transformation by having a line width and hence characteristic impedance different to that of the resonator. Lengths and widths of this transmission can be calculated by those skilled in the art.

As indicated above, the plasma generating device of the present invention contains a gas flow element configured to flow a gaseous stream through the discharge gap. The flow of gas delivered by the gas flow element can be in a variety of directions relative to the discharge gap, where in certain embodiments the gas flow is such that gas flows from the bottom of the discharge gap to the top of the discharge gap, such that when a plasma is struck from the gas a plasma jet is produced on the top surface of the discharge gap. In certain embodiments, the gas flow element flows gas in a direction that is substantially orthogonal, and in certain embodiments orthogonal, to the discharge gap. By orthogonal to the discharge gap is meant that the gas flows through the discharge gap from a point in the X/Z plane of the device. See e.g., FIGS. 1A and 1B which depict gas flowing from the ground plane 14 side of the device through substrate 12 and then through discharge gas 18. In other words, the gas flow is at a right angle (90°) (or substantially normal) to a line connecting the center of the discharge gap leads (dashed line D). By “substantially orthogonal” is meant that the angle of the gas flow through the discharge gap is ±15°, such as ±10°, including ±5° of orthogonal. In the embodiment shown in FIGS. 1A and B, the gas flow element 22 is a channel drilled (or bored) through the substrate and the ground plane of the plasma generating device. The width of the channel may vary, and in certain embodiments ranges from about 10 μm to about 1 mm, such as from about 20 μm to about 500 μm and including from about 140 μm to about 200 μm. In these embodiments, the gas flow element provides for a flow of gas in a direction that is substantially orthogonal to the substrate (and the discharge gap).

In other embodiments, the gas flow element can flow gas in a direction that is not orthogonal to the substrate. In certain of these embodiments, the gas flow delivered by the gas flow element is in substantially the same plane as the substrate surface on which the resonator is disposed (in the X/Y plane). In certain of these embodiments, the gas flow is substantially orthogonal to line D. As in the above embodiment, by “substantially orthogonal” is meant that the angle of the gas flow relative to line D is ±15°, such as ±10°, including ±5° of orthogonal line D.

The gas flow element can be configured in a variety of ways. In certain embodiments, the gas flow element is integral to the substrate. For example, the gas flow element may be etched, molded, or drilled directly onto/into the substrate and/or ground plane. In certain other embodiments, the gas flow element is a separate element that is capable of conveying a gas from a first location to second location, e.g., gas line, which is stably attached, e.g., affixed, to the structure in a manner sufficient to provide for the desired gas flow through the gap during use. The gas flow element may be fabricated from the same material as or a different material than the materials from which the other components of the device are fabricated, e.g., the substrate. The gas flow elements of the resonators of the invention are implemented in such a way as to not adversely affect the plasma generating function of the device. For example, if the dielectric constant of the material of the gas flow element affects the field lines above the resonator, the optimum matched conditions of the resonator may need to be adjusted. Optimization of such resonator function is within the capabilities of those of skill in the art.

In certain embodiments, the plasma generating device contains a gas feed connector (FIG. 1B, element 26) coupled to the gas flow element. The gas feed element is configured to attach a gas feed line to the gas flow element, and may include a number of different components, e.g., nozzles, lips, threads, gaskets, etc., made from a variety of different materials, e.g., rubber, silicone, metal solder etc. The gas feed connector can be disposed in any convenient location on the plasma generating device. For example, in the embodiment shown in FIG. 1B, the gas feed connector 26 is disposed on the ground plane of the device. In other embodiments, the gas feed connector for the gas flow element may be disposed on the substrate. In certain other embodiments, the gas feed connector may be detached from the substrate. The configuration of the connector will depend, at least in part, on the nature of the gas flow element being employed.

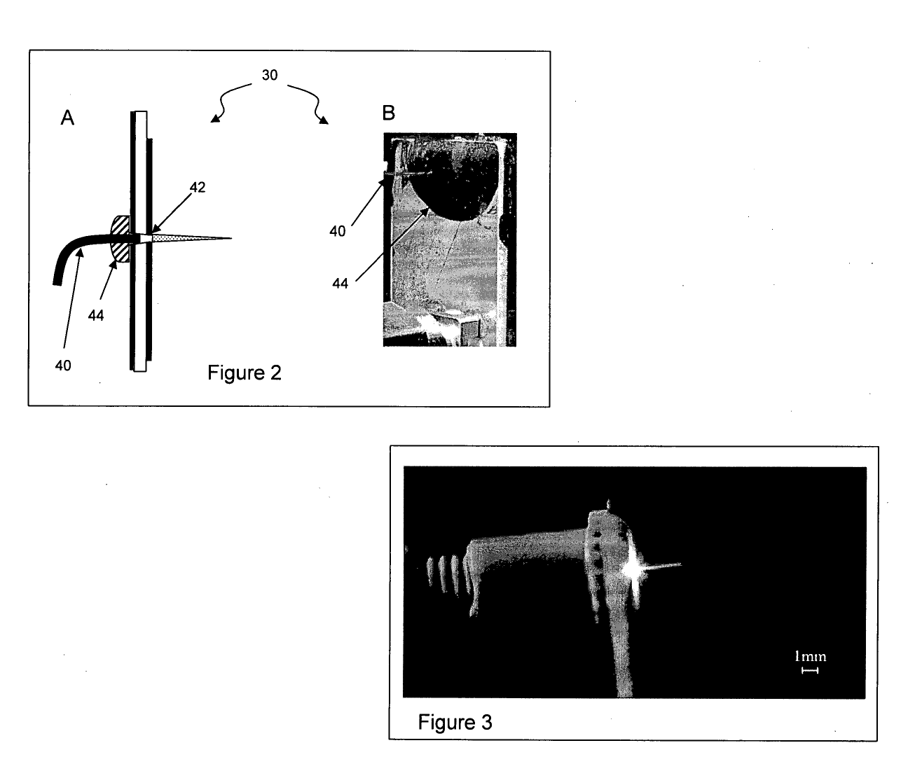

FIGS. 2A and 2B provide different views of an embodiment of the device 30 which employs a certain gas feed connector. In these embodiments, a fused silica capillary gas feed line 40 is press fitted into a conical gas flow element 42 (which is bored through the substrate and ground plane as in FIG. 1A). Gas line 40 is secured (e.g., “potted”) in place with silicon rubber connector 44 to ensure mechanical rigidity and strength of the connection of feed line 40 to flow element 42. FIG. 2B provides a photograph of an embodiment of a device having the connector shown in FIG. 2A.

Another example of a gas feed connector that finds use in the resonators of the invention is as follows. A stainless steel tube is press fit into a copper sleeve. This concentric copper/stainless fitting is then soldered onto the gas flow element (e.g., back of the substrate) while using a Tungsten wire threaded through both the substrate and the fitting to ensure location. This contact is rigid and contains no organic bonding agents (e.g., epoxy or silicone rubber). The copper wets to the solder and achieves the bond, while the stainless tube and the tungsten wire (mandrel) does not wet to the solder and prevents solder from entering the internal diameter of the gas flow element.

The plasma generating devices of the invention generate plasmas at the electric field across the discharge gap as opposed to from field lines between the microstrip resonant ring and the ground plane, which feature distinguishes the subject devices and plasmas generated using other plasma generating devices, e.g., DC, AC, RF or DBD (Dielectric Barrier Discharge) plasma generating devices, in which two contacts are required to sustain the field. The resonator of the plasma generating device of the present invention is essentially a one surface contact.

The above description of plasma generators according to various embodiments of the invention is provided for illustrative purposes only and is not meant to be limiting.

Systems

Also provided by the subject invention are systems that include the plasma generators, e.g., as described above. Aspects of these system embodiments of the invention include systems having a power source, a plasma generating device as described above, and a gas feed coupled to the gas flow element of the plasma generating device.

In certain embodiments, the resonator of the plasma generating device is coupled to a power source that supplies power to the resonator in a manner sufficient to generate plasma from gas flowing through the discharge gap of the resonator. The power supply is connected to the resonator using any convenient coupling element, e.g., such as the connectors described above. In certain embodiments, the power supply is of such a small size and compact construction such that it is integrated into associated equipment, e.g., so that it is easily transportable for field use or for other portable applications. In certain embodiments, the power source is an integrated circuit power amplifier. In certain of these embodiments, the system contains a feedback path between the resonator and an input of the power to provide oscillation and frequency control of the power source, e.g., at a power amplifier component of the power source.

In certain embodiments, the systems of the invention further contain a bias element (e.g., a bias coil). In these embodiments, the bias element may be positioned such that it has one end coupled to the resonator of the plasma generating device and the other end having a connector for application of a bias voltage. In these embodiments, the bias element has a microstripline length that is ¼ wavelength such that the DC power supply that is applying the additional voltage will be isolated from the RF power. The additional voltage provided by the bias element allows the plasma to be at a positive or negative voltage with respect to ground, and as such finds use in a number of embodiments. For example, ions produced from the plasma could be accelerated to a surface, or could be accelerated into another local microplasma for further ionization.

In embodiments of systems of the invention, the gas flow element of the plasma generating device is coupled to a gas feed (for example by connection of the gas feed to the gas feed connector of the gas flow element). The gas feed is configured to deliver a stream of gas, e.g., an inert or non-inert gas or gas mixture (as reviewed in greater detail below), to the gas flow element and through the discharge gap.

In certain embodiments, the plasma producing system of the invention further includes a detector configured to detect ionized species in the plasma produced by the system, where detectors of interest include, but are not limited to: optical spectrometers, mass spectrometers, ion mobility spectrometers, ion current etc. In certain other embodiments, the plasma producing system of the invention contains an analyte feed for delivering an analyte or other sample to the plasma. This analyte can be an output of a separation technique such as gas chromatography. The plasma producing systems of the invention can have a variety of configurations which will depend on the intended use of the system. For example, in certain embodiments, the system produces more than one plasma (i.e., the system contains more than one plasma generating device), e.g., as described in copending application Ser. No. 60/760,496; the disclosure of which is herein incorporated by reference.

Methods

Aspects of the invention also include methods of producing plasmas using the devices and systems of the invention, e.g., as described above. In using the subject devices and systems to produce a plasma, a gas is flowed through a discharge gap of a plasma generating device (e.g., through a gas flow element) and an electric discharge is produced at the discharge gap in a manner sufficient to strike a plasma from the gas flowing through the discharge gap.

In using the subject devices for plasma generation, a variety of different gases may be flowed through the discharge gap. Gasses of interest include, but are not limited to, inert gasses, e.g., argon, helium, xenon, nitrogen etc., as well as non-inert gasses/gas mixtures (e.g., atmospheric gasses).

The flow rate of gas through the discharge gap may also vary. In certain embodiments, the flow rate of gas through the discharge gap ranges from about 1 standard cubic centimeters per minute (sccm) to about 1000 sccm, such as from about 5 sccm to about 500 sccm and including from about 10 sccm to about 100 sccm.

The power applied to the resonator may vary depending on the particular configuration of the device, the environment and the desired properties of the plasma to be produced, so long is the applied power is sufficient to produce a discharge at the discharge gap that is sufficient to produce a plasma from the gas flowing through discharge gap. In certain embodiments, the power level employed to strike an atmospheric plasma using the systems of the invention ranges from 0.1 W to 50.0 W, such as from about 0.1 W to about 20 W and including from about 0.5 W to about 8 W.

In certain embodiments, the plasmas produced by the systems of the invention are non-equilibrium plasmas with temperatures in the range of from about 400° K to about 1000° K, such as from about 500° K to about 900° K and including from about 600° K to about 800° K. In certain embodiments, the plasma produced by the device may include one or more components not present in the gas flowed through the discharge gap. For example, a plasma generated using a plasma generating device of the invention may produce a plasma jet that extends into the atmosphere surrounding the discharge gap. As such, atmospheric components, e.g., N₂, etc, may be present in the plasma jet. The components of plasmas produced by the plasma generating devices of the invention will depending on the nature of the gas flowed through the discharge gap and the environment of the device.

The height of the plasma jet (e.g., element 32 of FIG. 1B) may vary and is dependent, at least in part, on the selected gas flow rate. In certain embodiments, the height of the produced plasma jet ranges from about 200 μm to about 20 mm, such as from about 300 μm to about 15 mm and including from about 500 μm to about 10 mm.

Utility

The above described plasma generator devices/systems and methods of using the same to produce plasmas find use in a variety of different applications. These applications include, but are not limited to, gas sensors, e.g., in which the optical emission from atoms and molecules is sensed by a spectrometer. From the wavelength and intensity of photon emission from the plasma, the quantity and type of gas constituents may be determined. The present invention may also be used as an ionizer in which the atoms and molecules in a gas stream are ionized and then identified by an electrometer, mass spectrometer or ion mobility spectrometer. The plasma produced by the subject devices/systems/methods may also be used a source of chemically reactive gas. For example, the plasma excitation of air produces molecular radicals that can be employed to render non-infectious many biological organisms such as bacteria. The radicals from the plasma may also be used to remediate toxic chemical substances such as chemical weapons and industrial waste products. In addition to plasma cleaning applications, the plasma may be part of a miniature chemical production system in which gas flows of reactant species are directed through the plasma where the chemicals react in a controlled manner to produce a useful chemical product. This type of miniature chemical process system allows for portable, point-of-use production of volatile, short-lived, or dangerous chemicals. In yet other embodiments, the plasmas are useful as a source of light in the visible, ultraviolet, and the vacuum ultraviolet parts of the spectrum. In all of these applications, a number of plasma generating devices of the invention may be combined to cover a linear region or an extended area.

A non-limiting list of applications for the plasma producing system of the invention includes: a) material processing applications at atmospheric pressures using reactive gases, e.g., etching applications, such as etching of Si, KAPTON®, Polyimides, etc.; deposition applications, e.g., deposition of SiO₂, diamond, etc.; local surface modification applications, e.g., application in which a surface is changed from hydrophobic to hydrophilic; b) local heat treatment of surfaces; c) gas analysis applications, e.g., where a plasma jet is used to analyze surrounding air, or other environments, for example when coupled with optical emission spectroscopy; or where an analyte is added to carrier gas when coupled with optical emission spectroscopy, e.g., as described in provisional application Ser. No. 60/760,560, the disclosure of which is incorporated herein by reference; d) surface cleaning verification applications, e.g., as described in copending application Ser. No. 60/760,570 and application Ser. No. 11/397,064 having attorney docket no. 10050869-1; the disclosures of which are herein incorporated by reference; e) non-contact electrical probing applications, e.g., as described in copending application Ser. No. 11/020,337 (attorney docket no. 10041087-1) the disclosure of which is herein incorporated by reference; f) in micro thruster applications, e.g., where the produced plasma is employed as a source of thrust, e.g., for moving an object from a first to a second location; and g) in micro light source applications, where the produced plasma is employed as a source of illumination.

The following examples are offered by way of illustration and not by way of limitation.

### EXAMPLES

FIG. 3 provides a photograph of a plasma producing system according to an embodiment of the invention producing a plasma jet. The plasma generating device depicted in FIG. 3 has a microstrip resonator ring configuration as shown in FIGS. 1A and 1B and was manufactured using 1 mm thick ceramic substrate with 6 μm thick Au microstrip resonator ring. A commercially available (Upchurch Scientific) connector was used to align the gas feed to the ground plane side of the gas flow element (a 140 μm-200 μm diameter channel drilled through the substrate to the microstrip discharge gap using a CO₂ laser). The plasma shown in FIG. 3 is produced by flowing He gas at a rate of 50 sccm and applying 39 dBm (2.6 GHz) of power to the microstrip resonant ring.

Ar or He gas can be used to produce the plasma jet, but lower strike powers are more readily achievable using He. Flow rates of approximately 10 sccm have been observed to achieve atmospheric plasma formation with either Ar or He. At moderate flow rates of He (e.g., 50 sccm as shown) an atmospheric plasma can be struck at just 27 dBm (0.5 W) for a 140 μm diameter hole. For low input powers, the plasma jet was observed to extend 0.1-1 mm in the visible range. At powers up to 39 dBm (7.9 W), the plasma was observed to extend several mm's (as shown in FIG. 3; scale bar is 1 mm). At high enough flow rates of inert gas, the involvement of the atmosphere constituents (predominantly N₂) is found to be minimized.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

What is claimed is:

1. A plasma generating device comprising:
a) a substrate having a first surface and a second surface;
b) a resonator having a discharge gap disposed on said first surface of said substrate;
c) a ground plane disposed on said second surface of said substrate;
d) a connector coupled to said resonator for connecting a power source to said resonator; and
e) a gas flow element configured to flow gas through said discharge gap.

2. The plasma generating device of claim 1, wherein said substrate is a planar substrate having a high dielectric constant.

3. The plasma generating device of claim 1, wherein said resonator has a microstrip resonant ring structure.

4. The plasma generating device of claim 1, wherein said microstrip resonant ring structure is circular.

5. The plasma generating device of claim 1, further comprising a transmission line that couples said connector to said resonator.

6. The plasma generating device of claim 1, wherein said connector and said discharge gap are disposed in positions on said resonator in a manner sufficient to provide an impedance matched to that of a power source.

7. The plasma generating device of claim 1, wherein said discharge gap has a width ranging from about 140 μm to about 200 μm.

8. The plasma generating device of claim 1, wherein said discharge gap extends through said substrate.

9. The plasma generating device of claim 1, wherein said gas flow element flows gas in a direction that is substantially orthogonal to said discharge gap.

10. The plasma generating device of claim 1, wherein said gas flow element is integral to said substrate.

11. The plasma generating device of claim 10, wherein said gas flow element is a channel bored through said substrate and said ground plane.

12. The plasma generating device of claim 1, wherein said gas flow element is affixed to said substrate.

13. The plasma generating device of claim 1, further comprising a gas feed connector coupled to said gas flow element.

14. A system for producing a plasma, said system comprising:
a) a power source;
b) a plasma generating device comprising:
i) a substrate having a first surface and a second surface;
ii) a resonator having a discharge gap disposed on said first surface of said substrate;
iii) a ground plane disposed on said second surface of said substrate;
iv) a connector coupled to said resonator for connecting said power source to said resonator; and
v) a gas flow element configured to flow gas through said discharge gap; and
c) a gas feed line coupled to said gas flow element.

15. The system of claim 14, further comprising a transmission line that couples said connector to said resonator.

16. The system of claim 14, wherein said gas flow element flows gas in a direction that is orthogonal to said discharge gap.

17. The system of claim 14, further comprising a detector.

18. The system of claim 17, further comprising an analyte delivery element.

19. The system of claim 14, further comprising a bias coil.

20. The system of claim 14, wherein said power source is present on said substrate.

21. The system of claim 20, wherein said power source is an integrated circuit power amplifier.

22. A method of producing a plasma comprising:
a) flowing a gas through a discharge gap of a plasma generating device; and
b) causing an electric discharge at said discharge gap sufficient to strike a plasma from said gas flowing through said discharge gap.

23. The method of claim 22, wherein said plasma generating device comprises:
a) a substrate having a first surface and a second surface;
b) a resonator disposed on said first surface of said substrate, wherein said resonator comprises said discharge gap;
c) a ground plane disposed on said second surface of said substrate;
d) a connector coupled to said resonator for connecting a power source to said resonator; and
e) a gas flow element configured to flow said gas through said discharge gap.

24. The method of claim 23, wherein said gas is flowed in a direction that is substantially orthogonal to said discharge gap.

25. The method of claim 24, wherein said gas is flowed through said discharge gap at a rate ranging from about 10 sccm to about 100 sccm.

26. The method of claim 22, wherein said gas is an inert gas.

27. The method of claim 22, wherein said method occurs under atmospheric conditions to produce an atmospheric plasma.

28. The method according to claim 27, wherein said electric discharge is caused by applying power to said resonator that ranges from about 0.5 W to about 8.0 W.

29. The method according to claim 28, wherein said method produces a plasma having a temperature ranging from about 600° K to about 800° K.
